(19) United States
(12) Patent Application Publication
(10) Pub. No.: US 2018/0339939 A1
(43) Pub. Date: Nov. 29, 2018

(54) GLASS ARTICLE AND DISPLAY DEVICE

(71) Applicant: Asahi Glass Company, Limited, Chiyoda-ku (JP)

(72) Inventors: Kyohei Hashimoto, Chiyoda-ku (JP); Tomohiro Takano, Chiyoda-ku (JP); Hitoshi Mishiro, Chiyoda-ku (JP); Minoru Tamada, Chiyoda-ku (JP)

(73) Assignee: Asahi Glass Company, Limited, Chiyoda-ku (JP)

(21) Appl. No.: 15/960,616

(22) Filed: Apr. 24, 2018

(30) Foreign Application Priority Data
May 23, 2017 (JP) 2017-102054

(51) Int. Cl. C03C 17/42; C03C 21/00; C03C 17/34; C03C 15/00; G02B 5/02; H05K 5/03; G02B 1/18; G02B 1/115

(52) U.S. Cl. CPC C03C 17/42; H05K 5/0017; C03C 17/3417; C03C 15/00; G02B 5/0278; H05K 5/03; G02B 5/0215; G02B 5/0268; G02B 1/18; G02B 1/115; C03C 2217/732; C03C 2217/77; C03C 2218/151; C03C 2218/31; C03C 2218/154; C03C 21/002

(57) ABSTRACT

A glass article includes a glass plate including a rugged surface configured to diffuse and reflect an external light formed on at least one of main surfaces; and a functional film formed on the rugged surface. A transmission haze of the glass article is 28% or less. On a surface of the functional film opposite to the glass plate, within a region with a visual field area of 60000 μm² observed by using a laser microscope, a pore representative diameter is less than 12 μm. An area ratio of a surface area A (μm²) of the surface of the functional film within the region to the visual field area (A/60000) is 1.02 or more and 1.07 or less.

### CROSS-REFERENCE TO RELATED APPLICATION

The present application is based on and claims benefit of priority under 35 U.S.C. § 119 of Japanese Patent Application No. 2017-102054, filed May 23, 2017. The contents of the application are incorporated herein by reference in their entirety.

### BACKGROUND OF THE INVENTION

### 1. Field of the Invention

The disclosure herein generally relates to a glass article and a display device using the same.

### 2. Description of the Related Art

Recently, particularly in mobile devices or on-vehicle apparatuses, a variety of image display devices, such as liquid crystal display (LCD) devices, have become often used. Conventionally, such an image display device has been configured of a glass plate arranged as a cover member. Moreover, a configuration of a substrate, in which a touch panel with a transparent electrode and a cover glass are integrated, also has been known.

In such an image display device, a person's fingers often come into contact with a surface of a glass plate. When a person's fingers come into contact with the surface, fat or the like is liable to adhere to the surface of the glass plate. Because when fat or the like adheres to the surface, visibility is affected by the fat or the like. Thus, an image display device having a glass plate on which an antifouling process was performed has been often used.

For example, a glass plate with an antifouling film, disclosed in Japanese Unexamined Patent Application Publication No. 2016-52992, includes a glass plate, a fluorine-containing organic silicon compound film that is an antifouling film arranged on a main surface of the glass plate. The main surface of the glass plate on which the antifouling film is formed is subjected to an antiglare processing. According to the antiglare processing, a rugged surface is formed. The rugged surface diffuses and reflects external light, such as sunlight or illumination light, and enhances an antiglare property for controlling reflection of external light.

### SUMMARY OF THE INVENTION

Glass articles having glass plates and functional films such as antifouling films formed on the glass plates have been developed and studied. The glass articles are used, for example, for cover glasses of image display devices such as liquid crystal display devices or organic electro luminescence (EL) display devices.

The glass plate is provided with a rugged surface that diffuses and reflects external light on at least one of main surfaces. A functional film is formed on the rugged surface. Because the functional film is sufficiently thin, a rugged shape of a surface of the functional film opposite to the glass plate is almost the same as the rugged shape of the rugged surface of the glass plate.

Recently, with enhancement in resolutions of image display devices, widths of pixels become narrower. Accordingly, the width of pixels may become smaller than a pore representative diameter of the rugged surface of the glass plate. Here, the pixel refers to a pixel of simple color (so-called subpixel) such as a red pixel, a blue pixel or a green pixel.

FIG. 1 is a diagram depicting a relation between a pore diameter of a rugged surface of a glass plate and a size of pixels (a red pixel 101R, a green pixel 101G, and a blue pixel 101B) according to a related art. The rugged surface 121 of the glass plate is provided with a plurality of pores, and each pore functions as a lens. A boundary between the adjacent pores has a shape of a sharp projection, which is particularly called as a ridge. For example, as illustrated in FIG. 1, when a width A101 of the green pixel 101G is sufficiently smaller than a pore diameter A102 of the rugged surface 121, lights from the plurality of pixels 101G that emit lights of the same color (the same wavelength) pass through one lens 122 and interfere with each other. Then, luminance unevenness occurs, and an image appears as a glittering object for eyes 102 of a user. Note that in FIG. 1, the pixels are arranged in the order of the red pixel 101R, the green pixel 101G and the blue pixel 101B. However, the present invention is not limited to the order.

In order to control against the glittering of an image, it is enough to make the pore diameter A102 of the rugged surface 102 smaller than four times the width A101 of the pixel. This is because a width of the display region 101 formed of the pixels (the red pixel 101R, the green pixel 101G and the blue pixel 101B) and a gap 1011 becomes greater than the pore diameter A102 of the rugged surface 121, and it becomes possible to prevent a plurality of lights of the same color (the same wavelength) from passing through the same lens 122. Moreover, because when the pore diameter A102 is small, a number of sharp ridges surrounding the lenses 122 is great, external light is liable to be diffused and reflected at ridges, and an excellent antiglare property is obtained.

However, when the pore diameter A102 is too small, the number of ridges becomes too great, and the ridges become too sharp. Thus, the glass article is easily scratched, and an anti-scratching property degrades. Moreover, a light from the display region 101 is liable to be diffused when the light passes through the rugged surface 101, an image is liable to be recognized as a blurred object, and an image quality degrades.

The present invention, in consideration of the above-described problem, aims at providing a glass article that is excellent at each of a performance of controlling against glittering of image, an antiglare property, an anti-scratching property, and an image quality, and a display device using the glass article.

According to an aspect of the present invention, a glass article including

a glass plate including a rugged surface configured to diffuse and reflect an external light formed on at least one of main surfaces; and

a functional film formed on the rugged surface,

a transmission haze of the glass article being 28% or less,

on a surface of the functional film opposite to the glass plate, within a region with a visual field area of 60000 μm² observed by using a laser microscope, a pore representative diameter being less than 12 μm, and

an area ratio of a surface area A (μm²) of the surface of the functional film within the region to the visual field area (A/60000) being 1.02 or more and 1.07 or less, is provided.

According to the aspect of the present invention, a glass article that is excellent at each of a performance of controlling against glittering of image, an antiglare property, an anti-scratching property, and an image quality, and a display device using the glass article are provided.

### BRIEF DESCRIPTION OF THE DRAWINGS

Other objects and further features of embodiments will become apparent from the following detailed description when read in conjunction with the accompanying drawings, in which:

FIG. 1 is a diagram depicting a relation between a pore diameter of a rugged surface of a glass plate and a size of pixels according to the related art;

FIG. 2 is a diagram depicting an example of a configuration of a glass article according to an embodiment;

FIG. 3 is a diagram depicting a relation between a pore diameter of a rugged surface of a glass plate and a size of pixels according to the embodiment;

FIG. 4 is a microscope photograph depicting a glass surface subjected to a frost treatment according to the embodiment;

FIG. 5 is a microscope photograph depicting a glass surface subjected to a frost treatment according to the related art;

FIG. 6 is a microscope photograph depicting a glass surface subjected to a secondary etching treatment after the frost treatment shown in FIG. 4;

FIG. 7 is a microscope photograph depicting a glass surface subjected to a secondary etching treatment after the frost treatment shown in FIG. 5;

FIG. 8 is a plan view depicting measurement points at which characteristic values of the glass articles manufactured in Examples 1 to 15 are measured; and

FIG. 9 is a graph depicting a relation between area ratios (A/60000) of the glass articles manufactured in Examples 1 to 15 and pencil hardness.

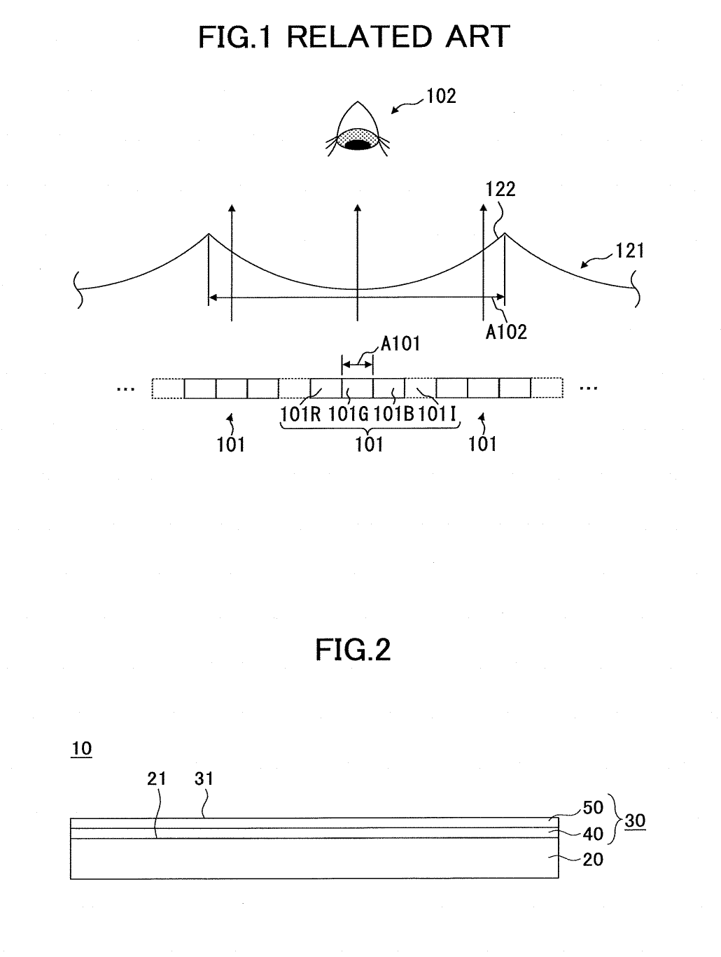

### DETAILED DESCRIPTION OF THE PREFERRED EMBODIMENTS

In the following, embodiments for implementing the present invention will be described with reference to the accompanying drawings. In each drawing, the same or corresponding reference numeral will be assigned to the same or corresponding member, and an explanation will be omitted.

<Glass Article>

FIG. 2 is a side view depicting a glass article according to an embodiment. Note that in FIG. 2, because a rugged shape of the rugged surface 21 of the glass plate 20 is small, illustration of the rugged shape will be omitted. Similarly, because a rugged shape of the surface 31 of the functional film 30 is small, illustration of the rugged shape will be omitted.

The glass article 10 is used as a cover glass of an image display device, such as a liquid crystal display or an organic EL (Electro Luminescence) display. The cover glass may include a touch sensor. The touch sensor detects a contact or an approach of an object such as a finger to a display. The image display device may be an on-vehicle apparatus.

The glass article 10 includes a glass plate 20 and a prescribed functional film 30 formed on the glass plate 20. In the following, configurations of the glass plate 20 and the functional film 30 will be described.

<Glass Plate>

The glass plate 20 has a rugged surface 21, which diffuses and reflects an external light such as a solar light or an illumination light, on at least one of main surfaces. The rugged surface 21 diffuses and reflects an external light, and thereby enhances an antiglare property for controlling against a glare of the external light. According to the above-described configuration, visibility for an image displayed on the image display device can be enhanced. Note that a rugged shape fabrication processing for forming the rugged surface 21 will be described later.

The glass plate 20 is formed of an alkali-free glass, a soda lime glass, an aluminosilicate glass, or the like. When the glass plate 20 is a chemical strengthened glass, which will be described later, the glass plate 20 is formed of a glass including alkali metal, specifically a soda lime glass, an aluminosilicate glass, or the like.

The glass plate 20 includes glasses having compositions that satisfy any one of the following requirements of glasses (i) to (vii), for example. Note that the compositions of the glasses (i) to (v) are expressed in percent by mol in terms of oxide, and the compositions of the glasses (vi) and (vii) are expressed in percent by mass in terms of oxide. The composition of the glass plate 20 may be obtained by analyzing a composition of a central portion of the glass in the plate thickness direction using a publicly known method, such as EDX (Energy Dispersive X-ray spectroscopy) or ICP (Inductively Coupled Plasma).

(i) a glass including SiO₂ of 50% to 80%, Al₂O₃ of 2% to 25%, Li₂O of 0% to 10%, Na₂O of 0% to 18%, K₂O of 0% to 10%, MgO of 0% to 15%, CaO of 0% to 5%, and ZrO₂ of 0% to 5%;

(ii) a glass including SiO₂ of 50% to 74%, Al₂O₃ of 1% to 10%, Na₂O of 6% to 14%, K₂O of 3% to 11%, MgO of 2% to 15%, CaO of 0% to 6%, and ZrO₂ of 0% to 5%, where a sum of contained amounts of SiO₂ and Al₂O₃ is 75% or less, a sum of contained amounts of Na₂O and K₂O is 12% to 25%, and a sum of contained amounts of MgO and CaO is 7% to 15%;

(iii) a glass including SiO₂ of 68% to 80%, Al₂O₃ of 4% to 10%, Na₂O of 5% to 15%, K₂O of 0% to 1%, MgO of 4% to 15% and ZrO₂ of 0% to 1%, where a sum of contained amounts of SiO₂ and Al₂O₃ is 80% or less;

(iv) a glass including SiO₂ of 67% to 75%, Al₂O₃ of 0% to 4%, Na₂O of 7% to 15%, K₂O of 1% to 9%, MgO of 6% to 14%, CaO of 0% to 1% and ZrO₂ of 0% to 1.5%, where a sum of contained amounts of SiO₂ and Al₂O₃ is 71% to 75%, and a sum of contained amounts of Na₂O and K₂O is 12% to 20%;

(v) a glass including SiO₂ of 60% to 75%, Al₂O₃ of 0.5% to 8%, Na₂O of 10% to 18%, K₂O of 0% to 5%, MgO of 6% to 15%, and CaO of 0% to 8%;

(vi) a glass including SiO₂ of 63% to 75%, Al₂O₃ of 3% to 12%, MgO of 3% to 10%, CaO of 0.5% to 10%, SrO of 0% to 3%, BaO of 0% to 3%, Na₂O of 10% to 18%, K₂O of 0% to 8%, ZrO₂ of 0% to 3%, and Fe₂O₃ of 0.005% to 0.25%, where a ratio of contained amounts R₂O/Al₂O₃ (in the formula, R₂O represents Na₂O and K₂O) is 2.0 or more and 4.6 or less; and

(vii) a glass including SiO₂ of 66% to 75%, Al₂O₃ of 0% to 3%, MgO of 1% to 9%, CaO of 1% to 12%, Na₂O of 10% to 16%, and K₂O of 0% to 5%.

From a viewpoint of enhancement of strength, the glass plate 20 is preferably a chemical strengthened glass that was subjected to a chemical strengthening processing. The chemical strengthening processing is performed after the rugged shape fabricating processing for forming the rugged surface 21. In the chemical strengthening processing, an alkali metal ion with a smaller ion radius (e.g. Na ion) on a surface of a glass is replaced by an alkali metal ion with greater ion radius (e.g. K ion). According to the processing, a compressive stress layer is formed on the surface.

The chemical strengthened glass has a compressive stress layer on a surface, such as the rugged surface 21. A surface compressive stress of the compressive stress layer may be 600 MPa or more, for example. Although a composition of the compressive stress layer is slightly different from the composition before the chemical strengthening processing, a composition of a portion deeper than the compressive stress layer is almost the same as the composition before the chemical strengthening processing.

The chemical strengthening processing is performed by immersing the glass plate 20 including alkali metal ions with smaller ion radii (e.g. Na ions) in a molten salt including alkali metal ions with greater ion radii (e.g. K ions). The molten salt is selected according to a type of glass of the glass plate 20. For example, the molten salt includes potassium nitride, sodium sulfate, potassium sulfate, sodium chloride and potassium chloride. The aforementioned molten salt may be used alone, or a plurality of types of molten salts may be combined for use.

A heating temperature for the molten salt is preferably 350° C. or higher, and more preferably 380° C. or higher. Moreover, the heating temperature is preferably 500° C. or lower, and more preferably 480° C. or lower. By setting the heating temperature for the molten salt to 350° C. or higher, the chemical strengthening processing can be prevented from being inhibited by a lowered ion exchange rate. Moreover, by setting the heating temperature for the molten salt to 500° C. or lower, the molten salt can be prevented from resolving or degrading.

A length of bringing the glass plate 20 into contact with the molten salt is preferably 1 hour or more in order to give a sufficient compressive stress, and more preferably 2 hours or more. Moreover, because a prolonged ion exchange decreases a productivity and reduces a compressive stress value due to relaxation, the length is preferably 24 hours or less, and more preferably 20 hours or less.

Note that the condition for the chemical strengthening processing is not particularly limited, but can be selected according to the type of glass for the chemical strengthening processing, a surface compressive stress that is required, or the like.

The glass plate 20 has a plane plate shape, as illustrated in FIG. 2, but may have a curved plate shape. The shape of the glass plate 20 is not particularly limited.

<Functional Film>

The functional film 30 is formed on the rugged surface 21 of the glass plate 20. A summed thickness of the functional film 30 is 100 nm to 500 nm. Because the functional film 30 is sufficiently thin, a rugged shape of a surface 31 of the functional film 30 opposite to the glass plate 20 (in the following, referred to as a “surface 31 of the functional film 30”) is almost the same as the rugged shape of the rugged surface 21. Note that the rugged shape of the surface 31 of the functional film 30 will be described later.

The functional film 30 may have at least a low reflection film 40 that controls against a reflection of external light. According to the configuration, a reflectance of a surface of the glass plate can be reduced, the antiglare property for controlling reflection of external light can be further enhanced, and the visibility for an image can be further improved.

The functional film 30 may have an antifouling film 50 for controlling against a fouling on a surface of the glass article 10 in addition to the low reflection film 40. In the case where the image display device is a touch panel, an adhesion of a fingerprint of a finger that touches a display can be controlled.

<Low Reflection Film>

The low reflection film 40 is not particularly limited. For example, the low reflection film 40 may have a structure in which a high refractive index layer and a low refractive index layer are laminated. One layer of the high refractive index layer and one layer of the low refractive index layer may be arranged. Moreover, two layers of the high refractive index layer and two layers of the low refractive index layer may be arranged. In this case, the high refractive index layers and the low refractive index layers may be alternately laminated.

The low reflection film 40 preferably has a multi-layered structure, in which a plurality of layers are laminated, in order to obtain a sufficient anti-reflection performance. A number of layers configuring the low reflection film 40 is, for example, 2 or more and 6 or less, and preferably 2 or more and 4 or less.

Materials of the high refractive index layer and the low refractive index layer are not particularly limited. The materials can be selected taking into account a required degree of control against reflection, a required productivity, or the like. As the material configuring the high refractive index layer, for example, one or more types of materials selected from niobium oxide (Nb₂O₅), titanium oxide (TiO₂), zirconium oxide (ZrO₂), silicon nitride (SiN), and tantalum oxide (Ta₂O₅) can be preferably used. Moreover, as the material configuring the low refractive index layer, silicon oxide (SiO₂) can be preferably used.

For the high refractive index layer, according to productivity and a degree of a refractive index, particularly niobium oxide is preferably used. Thus, the low reflection film 40 is preferably configured of a laminated body of a niobium oxide layer and a silicon oxide layer.

Note that in order to enhance adhesiveness between the low reflection film 40 and the glass plate 20, a surface modification layer for modifying a surface of the glass plate 20 may be formed between the low reflection film 40 and the glass plate 20.

<Antifouling Film>

The antifouling film 50 controls against a fouling on a surface of the glass article 10. The antifouling film 50 is arranged on a surface opposite to the glass plate 20 with reference to the low reflection film 40. The antifouling film 50 is formed of, for example, a fluorine-containing organic silicon compound.

The fluorine-containing organic silicon compound will be described. As a fluorine-containing organic silicon compound used in the embodiment, a compound can be used without being particularly limited, as long as the compound gives an antifouling property, a water repellency, and an oil repellency.

Such a fluorine-containing organic silicon compound includes, for example, a fluorine-containing organic silicon compound having one or more groups selected from a group including a polyfluoropolyether group, a polyfluoroalkylene group, and a polyfluoroalkyl group. Note that the polyfluoropolyether group is a divalent group having a structure in which a polyfluoroalkylene group and an ether type oxygen atom are alternately coupled.

A specific example of the fluorine-containing organic silicon compound having one or more groups selected from a group including a polyfluoropolyether group, a polyfluoroalkylene group, and a polyfluoroalkyl group, includes compounds expressed by the following general formulas (I) to (V) or the like.

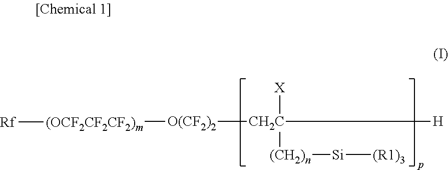

In Formula (I), Rf is a straight-chain polyfluoroalkyl group with 1 to 16 carbons (an alkyl group includes, for example, a methyl group, an ethyl group, an n-propyl group, an isopropyl group, and an n-butyl group), X is a hydrogen atom or a lower alkyl group with 1 to 5 carbons (for example, including a methyl group, an ethyl group, an n-propyl group, an isopropyl group, and an n-butyl group), R1 is a hydrolysable group (for example, including an amino group or an alkoxy group) or a halogen atom (for example, including fluorine, chlorine, bromine, or iodine), m is an integer of 1 to 50, preferably 1 to 30, n is an integer of 0 to 2, preferably 1 to 2, p is an integer of 1 to 10, preferably 1 to 8.

[Chemical 2]

C_{q}F_{2q+1}CH₂CH₂Si(NH₂)₃ (II)

In Formula (II), q is an integer greater than or equal to 1, preferably 2 to 20.

The compound expressed by the general formula

(II) includes, for example, n-trifluoro (1,1,2,2-tetrahydro) propylsilazane (n-CF₃CH₂CH₂Si(NH₂)₃), and n-heptafluoro (1,1,2,2-tetrahydro) pentylsilazane (n-C₃F₇CH₂CH₂Si(NH₂)₃)

[Chemical 3]

C_{q}F_{2q+1}CH₂CH₂Si(OCH₃)₃ (III)

In Formula (III), q is an integer greater than or equal to 1, preferably 1 to 20.

The compound expressed by the general formula (III) includes, for example, 2-(perfluorooctyl) ethyltrimethoxysilane (n-C₈F₁₇CH₂CH₂Si(OCH₃)₃).

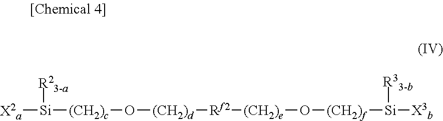

In Formula (IV), R^{f2} is a divalent straight-chain polyfluoropolyether group expressed by —(OC₃F₆)ₛ—(OC₂F₄)ₜ—(OCF₂)u- (s, t and ii are integers of 0 to 200, and independent from each other). R² and R³ are independent from each other and are monovalent hydrocarbon groups with 1 to 8 carbons (for example, a methyl group, an ethyl group, an n-propyl group, an isopropyl group, or an n-butyl group). X² and X³ are independent from each other and are hydrolysable groups (for example, an amino group, an alkoxy group, an acyloxy group, an alkenyloxy group, or an isocyanate group), or halogen atoms (for example, a fluorine atom, a chlorine atom, a bromine atom, or an iodine atom), d and e are independent integers from each other and are 1 or 2, c and f are independent integers from each other and are 1 to 5 (preferably 1 or 2), and a and b are independent integers from each other and are 2 or 3.

In R^{f2} in Formula (IV), a sum of the integers s+t+u preferably falls within a range of 20 to 300, and more preferably falls within a range of 25 to 100. Moreover, R² and R³ are preferably methyl groups, ethyl groups or butyl groups. The hydrolysable groups indicated by X² and X³ are more preferably alkoxy groups with 1 to 6 carbons, and are particularly preferably methoxy groups or ethoxy groups. Moreover, a and b are preferably 3, respectively.

[Chemical 5]

F—(CF₂)ᵥ—(OC₃F₆)_{w}—(OC₂F₄)_{y}—(OCF₂)_{z}(CH₂)ₕO(CH₂)ᵢ—Si(X⁴)₃₋ₖ(R⁴)ₖ (V)

In Formula (V), v is an integer of 1 to 3, x, y and z are independent from each other and are integers of 0 to 200, h is an integer of 1 or 2, I is an integer of 2 to 20, X⁴ is a hydrolysable group, R⁴ is a straight-chain or branched hydrocarbon group with 1 to 22 carbons, k is an integer of 0 to 2, a sum of integers w+y+z preferably falls within a range of 20 to 300, and more preferably falls within a range of 25 to 100. Moreover, i preferably falls within a range of 2 to 10. X⁴ is preferably an alkoxy group with 1 to 6 carbons, and is more preferably a methoxy group or an ethoxy group. R⁴ is more preferably an alkyl group with 1 to 10 carbons.

Moreover, as a commercially supplied fluorine-containing organic silicon compound having one or more groups selected from a group including a polyfluoropolyether group, a polyfluoroalkylene group, and a polyfluoroalkyl group, KP-801 (trade name, by Shin-Etsu Chemical Co., Ltd.), KY178 (trade name, by Shin-Etsu Chemical Co., Ltd.), KY-130 (trade name, by Shin-Etsu Chemical Co., Ltd.), KY-185 (trade name, by Shin-Etsu Chemical Co., Ltd.), Optool (trademark registered) DSX and Optool AES (both are trade names, by Daikin Industries, Ltd.) are preferably used.

Note that a fluorine-containing organic silicon compound is generally stored being mixed with a solvent such as a fluorine type solvent, in order to control against degradation due to a reaction with water from the air. However, when the compound is provided to a film deposition processing in a state where the compound contains the solvent, the solvent may have an unfavorable effect to a durability of the obtained thin film, or the like.

Accordingly, in the embodiment, a fluorine-containing organic silicon compound, in which a solvent is removed in advance before heating in a heating container, or a fluorine-containing organic silicon compound that has not been diluted with a solvent (a solvent has not been added) is preferably used. For example, a concentration of a solvent contained in a fluorine-containing organic silicon compound solution is preferably 1 mol % or less, and is more preferably 0.2 mol % or less. A fluorine-containing organic silicon compound that does not contain a solvent is particularly preferable.

Note that the solvent, which is used when the fluorine-containing organic silicon compound is stored, includes, for example, perfluorohexane, metaxylenehexafluoride (c₆H₄(CF₃)₂), hydrofluoropolyether, HFE7200/7100 (trade name, by Sumitomo 3M Limited, HFE7200 is expressed by C₄F₉OC₂H₅, and HFE7100 is expressed by C₄F₉OCH₃).

The solvent (thinner) removal process from the fluorine-containing organic silicon compound solution including a fluorine type solvent can be performed, for example, by performing a vacuum exhaust for a container containing the fluorine-containing organic silicon compound solution.

A length of time for performing the vacuum exhaust is not limited, because the length of time varies according to an exhaust capacity of an exhaust line and a vacuum pump, an amount of the solution, and the like. However, the length of time may be, for example, greater than or equal to 10 hours.

A method of depositing the antifouling film 50 is not particularly limited. However, the antifouling film 50 is preferably deposited by a vacuum evaporation method using the aforementioned material.

Moreover, the aforementioned solvent removal process can be performed by introducing the fluorine-containing organic silicon compound solution into the heating container of a deposition apparatus for depositing the antifouling film 50, and then performing a vacuum exhaust inside the heating container at a room temperature before increasing the temperature. Moreover, a solvent may be removed in advance before introducing the solution into the heating container by using an evaporator or the like.

However, as described above, the fluorine-containing organic silicon compound that contains a small amount of solvent or that does not contain solvent is liable to be degraded by contact with the air, compared with the compound containing solvent.

Accordingly, for a storing container for the fluorine-containing organic silicon compound that contains a small amount of solvent or does not contain solvent, it is preferable to use a container, in which a gas inside is replaced by an inert gas such as a nitrogen gas and which can be sealed, and to make a length of time of exposure to an air or a length of time of contact with air as short as possible.

Specifically, it is preferable to introduce the fluorine-containing organic silicon compound into the heating container of the deposition apparatus for depositing the antifouling film 50 immediately after opening the storing container. Then, after introducing the compound, it is preferable to remove an air contained in the heating container by vacuumizing an inside of the heating container or replacing the air by an inert gas such as a nitrogen gas or a rare gas. Furthermore, a storing container (storage container) is preferably connected to the heating container via a piping with a valve so that the compound can be introduced from the storage container into the heating container of the manufacturing apparatus without contacting the air.

Then, after introducing the fluorine-contained organic silicon compound into the heating container, and after vacuumizing an inside of the heating container or replacing the air inside the container by an inert gas, it is preferable to immediately start heating for deposition.

In the description of the embodiment, as the deposition method for the antifouling film 50, an example of using the fluorine-containing organic silicon compound of a solution or a stock liquid has been described. However, the present invention is not limited to this. The other method includes, for example, a method of using a commercially supplied so-called evaporation pellet (e.g. SURFCLEAR by Canon Optron, Inc.) in which a certain amount of fluorine-containing organic silicon compound is impregnated in a porous metal (e.g. tin or copper) or a fibrous metal (e.g. a stainless steel) in advance. In this case, an antifouling film 50 can be easily deposited with a deposition source of the pellet with an amount according to a capacity of the deposition apparatus or a required film thickness.

<Characteristics of Glass Article>

A Martens hardness of the glass article 10 is measured by placing the glass article 10 with the functional film 30 facing upward, and pushing an indenter into the functional film 30 from above the glass article 10. The Martens hardness of the glass article 10 is measured in conformity with ISO 14577-1:2002.

The Martens hardness of the glass article 10 is preferably 2.0 GPa or more. When the Martens hardness is 2.0 GPa or mode, a sufficient scratch resistance is obtained, and the functional film 30 is not liable to be scratched.

A pencil hardness of the glass article 10 is measured in conformity with JIS K5600-5-4:1999 (ISO 15184:1996) “scratch hardness (pencil method)”.

The pencil hardness of the glass article 10 is preferably 7H or more, is more preferably 8H or more, and is further preferably 10H. When the pencil hardness of the glass article 10 is 7H or more, a sufficient scratch resistance is obtained, and the functional film 30 is not liable to be broken. Note that a pencil used in the measurement is not particularly limited, and for example a UNI series (trademark registered) by Mitsubishi Pencil Co., Ltd. can be used.

A transmission haze of the glass article 10 is a proportion (percentage) of transmitted light deviated from an incident light by an angle of 0.044 rad(2.5°) or more due to a forward scattering out of transmitted lights that are transmitted through the glass article 10 from the glass plate 20 toward the functional film 30. The transmission haze is measured in conformity with JIS K7136:2000 (ISO 14782:1999).

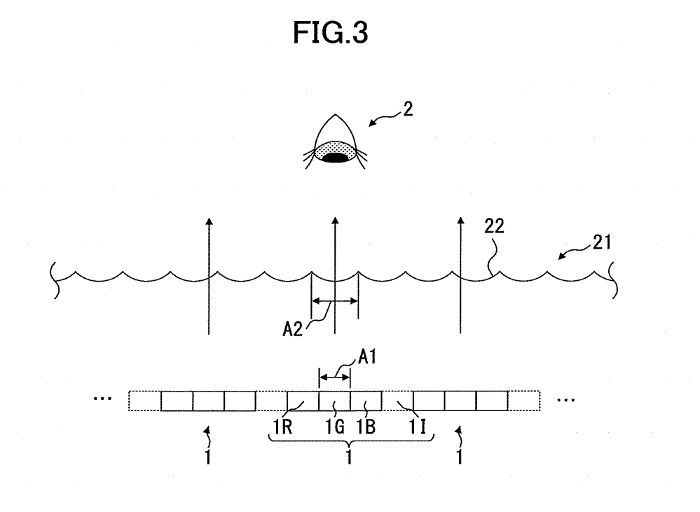

The transmission haze of the glass article 10 is 28% or less. When the transmission haze of the glass article 10 is 28% or less, a diffusion of a light from the pixels (red pixel 1R, green pixel 1G, blue pixel 1B) (See FIG. 3) configuring the display region 1 at the rugged surface 21 when the light transmits through the rugged surface 21 can be controlled, blur of an image can be controlled, and an image with an excellent image quality can be seen. The transmission haze of the glass article 10 is preferably 25% or less, and is more preferably 20% or less. Note that in FIG. 3, pixels are arranged in the order of the red pixel 1R, the green pixel 1G, and the blue pixel 1B. However, the present invention is not limited to this.

A rugged shape of the surface 31 of the functional film 30 is measured by using a laser microscope. A range for measurement is a range of a visual field area of 60000 μm² (300 μm×200 μm). Here, the visual field area means a projected area when the surface 31 of the functional film 30 is projected onto a plane surface that is orthogonal to a normal line of a least square plane surface (plane surface approximated by the least-square method) of the surface 31.

A pore representative diameter of the surface 31 of the functional film 30 is calculated according to the following procedure based on results of measurement by the laser microscope. First, a height from a reference level at each measurement point of the surface 31 is obtained. The reference level was subjected to an inclination correction, and is parallel to the least square plane surface of the surface 31. Next, in a cumulative distribution of height (number criterion), a height corresponding to the cumulative number of 90% is set to a reference height. The reference height is a height when measurement points are arranged in an order of height, a cumulative number of measurement points is counted in the order of height from lowest to highest, and the cumulative number becomes 90% of the total number of the measurement points.

Next, an image by the laser microscope is binarized into a part in which a height exceeds the reference height, and a part in which a height is less than or equal to the reference height. Then, the part in which the height is less than or equal to the reference height is set to a pore. For each pore, a size in the longitudinal direction (long diameter) and a size in a direction orthogonal to the longitudinal direction (short diameter) are obtained, and a root mean square of the long diameter and the short diameter (a square root of an average of a square of the long diameter and a square of the short diameter) is calculated. The calculated root means square is set to a pore diameter of each pore.

Then, in a cumulative distribution of a pore diameter (number criterion), a pore distribution corresponding to the cumulative number of 90% is set to a pore representative diameter. The pore representative diameter is a pore diameter when pores are arranged in an order of a pore diameter, a cumulative number of pores is counted in the order of a pore diameter from smallest to greatest, and the cumulative number becomes 90% of the total number of the pores.

FIG. 3 is a diagram depicting an example of a relation between a pore diameter of a rugged surface of the glass plate according to the embodiment and a size of pixels. As illustrated in FIG. 3, the rugged surface 21 is formed so that the pore diameter A2 of the rugged surface 21 is less than four times a width A1 of the pixel (for example, the green pixel 1G). On the rugged surface 21, a functional film 30 is formed. Because the functional film 30 is sufficiently thin, a rugged shape of a surface 31 of the functional film 30 is approximately the same as a rugged shape of the rugged surface 21 of the glass plate 20.

A pore representative diameter of the surface 31 of the functional film 30 is less than 12 μm. When the pore representative diameter of a surface of the functional film 30 is less than 12 μm, in the case where the width A1 of the pixel (for example, the green pixel 1G) is 3 μm or more, i.e. when the width of the display region 1 is 12 μm or more, a glittering of an image can be controlled. A lower limit of the pore representative diameter of the surface of the functional film 30 is not particularly limited, and is preferably 3 μm or more, for example, and more preferably 6 μm or more.

Note that the pore representative diameter of the surface 31 of the functional film 30 may be less than four times the width A1 of the pixel (for example, the green pixel 1G), and may be less than the width of the display region 1.

The pore representative diameter of the surface 31 of the functional film 30 may be, for example, 5 μm or more, from a viewpoint of workability of the rugged surface 21 of the glass plate 20.

In the surface 31 of the functional film 30, an area ratio of a surface area A (μm²) to a visual field area (A/60000) is 1.02 or more and 1.07 or less. The surface area A is an area, to which effects of the rugged shape of the surface are added. The area ratio (A/60000) represents a number of ridges surrounding pores and a sharpness of ridges. For an increasing area ratio (A/60000), both the number and the sharpness of ridges increase accordingly.

When the area ratio (A/60000) of the surface 31 of the functional film 30 is 1.07 or less, the number of ridges and the sharpness of the ridges are reduced, a scratch can be prevented from occurring, and an anti-scratching property of the pencil hardness of 7H or more can be obtained.

When the area ratio (A/60000) of the surface 31 of the functional film 30 is 1.06 or less, the number of ridges and the sharpness of the ridges are further reduced, and scratch can be further prevented from occurring, and an anti-scratching property of the pencil hardness of 9H or more can be obtained.

In contrast, when the area ratio (A/60000) of the surface 31 of the functional film 30 is 1.02 or more, by the ridges of the surface 31, an external light is diffused and reflected. Thus, a glare of the external light can be controlled, and visibility for an image can be enhanced.

In the surface 31 of the functional film 30, as described above, the pore representative diameter is less than 12 μm, and the area ratio (A/60000) is 1.02 or more and 1.07 or less. Moreover, as described above, the rugged shape of the surface 31 of the functional film 30 is approximately the same as the rugged shape of the rugged surface 21 of the glass plate 20. Therefore, in the rugged surface 21 of the glass plate 20, a pore representative diameter is less than 12 μm, and an area ratio (A/60000) is 1.02 or more and 1.07 or less.

The rugged surface 21 of the glass plate 20 is formed by a rugged processing treatment. The rugged processing treatment includes, for example, a primary etching treatment (in the following, also referred to as a “frost treatment”), and a secondary etching treatment.

In the frost treatment, different from Japanese Unexamined Patent Application Publication No. 2016-52992, a mixed solution of hydrogen fluoride and potassium fluoride is used as an etching liquid for the glass plate 20.

Hydrogen fluoride reacts with an SiO₂ component of glass, as illustrated in the following reaction formula (VI) and elutes an SiF₆ ion in the etching liquid.

[Chemical 6]

SiO₂+6HF→H₂SiF₆+2H₂O (VI)

In contrast, potassium fluoride is coupled to an SiF₆ ion eluted in the etching liquid, as illustrated in the following reaction formula (VII), and deposits K₂SiF₆ on a glass surface.

[Chemical 7]

H₂SiF₆+2KF→K₂SiF₆+4HF (VII)

Because K₂SiF₆ deposited on the glass surface is poorly-soluble by hydrogen fluoride, K₂SiF₆ functions as a mask that protects a glass from an etching by hydrogen fluoride. A part of the glass surface that is not covered with the mask is selectively etched. As a result, a rugged shape is formed on the glass surface.

Note that Japanese Unexamined Patent Application Publication No. 2016-52992 discloses the frost treatment in which a mixed solution of hydrogen fluoride and ammonium fluoride is used as an etching liquid for the glass plate.

Ammonium fluoride is coupled to an SiF₆ ion eluted in the etching liquid, as illustrated in the following reaction formula (VIII), and deposits (NH₄)₂SiF₆ on a glass surface.

[Chemical 8]

H₂SiF₆+2NH₄HF₂→(NH₄)₂SiF₆+4HF (VIII)

Because (NH₄)₂SiF₆ deposited on the glass surface is poorly-soluble by hydrogen fluoride, (NH₄)₂SiF₆ functions as a mask that protects a glass from an etching by hydrogen fluoride. A part of the glass surface that is not covered with the mask is selectively etched. As a result, a rugged shape is formed on the glass surface.

In the case of using potassium fluoride for a masking agent as in the embodiment, compared with the case of using ammonium fluoride for a masking agent as disclosed in Japanese Unexamined Patent Application Publication No. 2016-52992, a deposition rate is higher. Thus, a mask quickly covers the glass surface, and fine pores are likely to be formed on the glass surface.

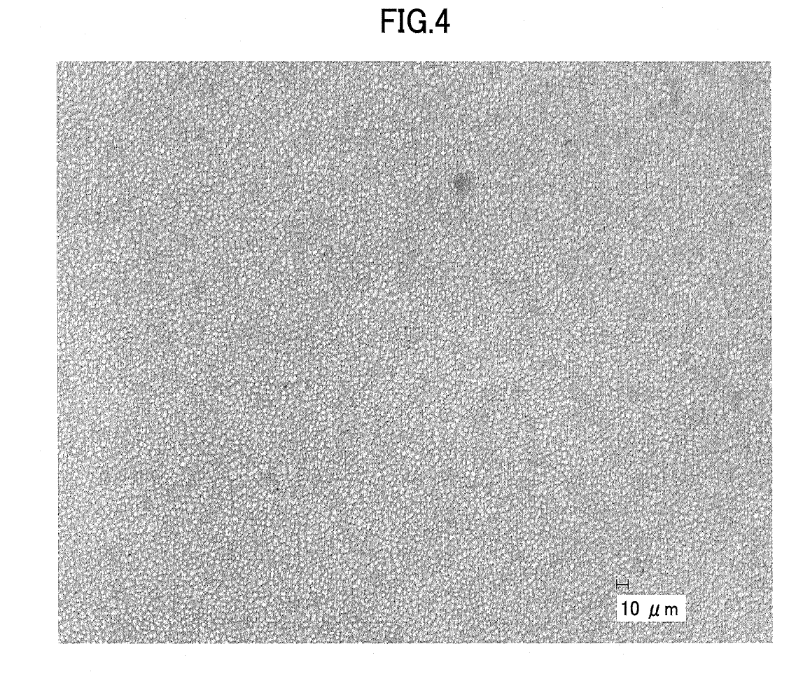

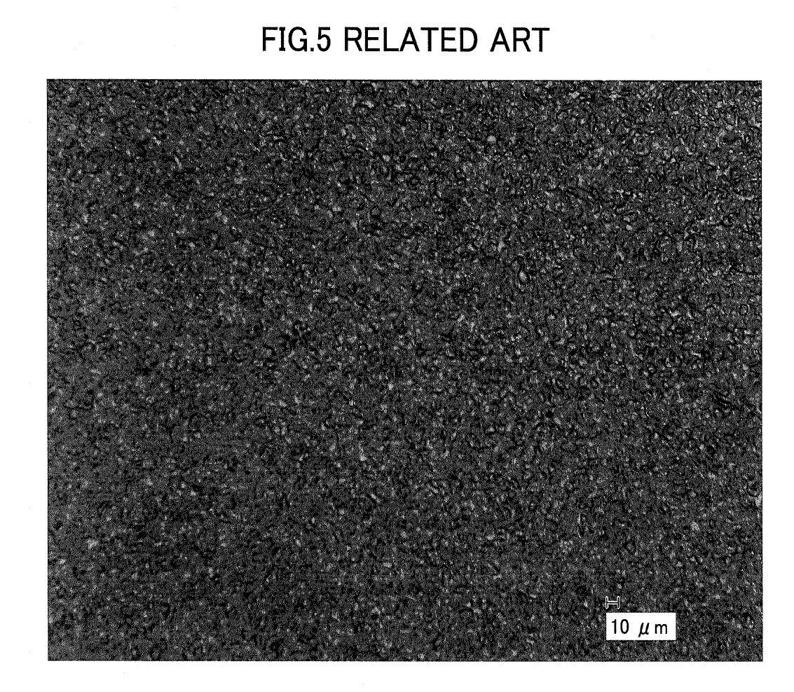

FIG. 4 is a microscope photograph depicting a glass surface obtained by the frost treatment according to the embodiment. In the frost treatment for FIG. 4, an etching liquid containing potassium fluoride for a masking agent was used. FIG. 5 is a microscope photograph depicting a glass surface obtained by the frost treatment according to the related art. In the frost treatment for FIG. 5, an etching liquid containing ammonium fluoride for a masking agent was used.

When FIG. 4 and FIG. 5 are compared, it is clear that, by using potassium fluoride for a masking agent, the pores obtained by the frost treatment can be made finer, compared with the case of using ammonium fluoride for a masking agent.

Note that a deposition rate for deposits can also be adjusted by a concentration ratio between potassium fluoride and hydrogen fluoride.

In the secondary etching treatment, in the same way as in Japanese Unexamined Patent Application Publication No. 2016-52992, a solution containing hydrogen fluoride as a main ingredient is used as an etching liquid for the glass plate 20. The etching liquid may contain, in addition to hydrogen fluoride, hydrochloric acid, nitric acid, citric acid, or the like. By containing the aforementioned acids, it becomes possible to control against an occurrence of a localized deposition reaction, in which an alkaline component in the glass plate 20 reacts with hydrogen fluoride, and to make the etching progress uniformly in a plane.

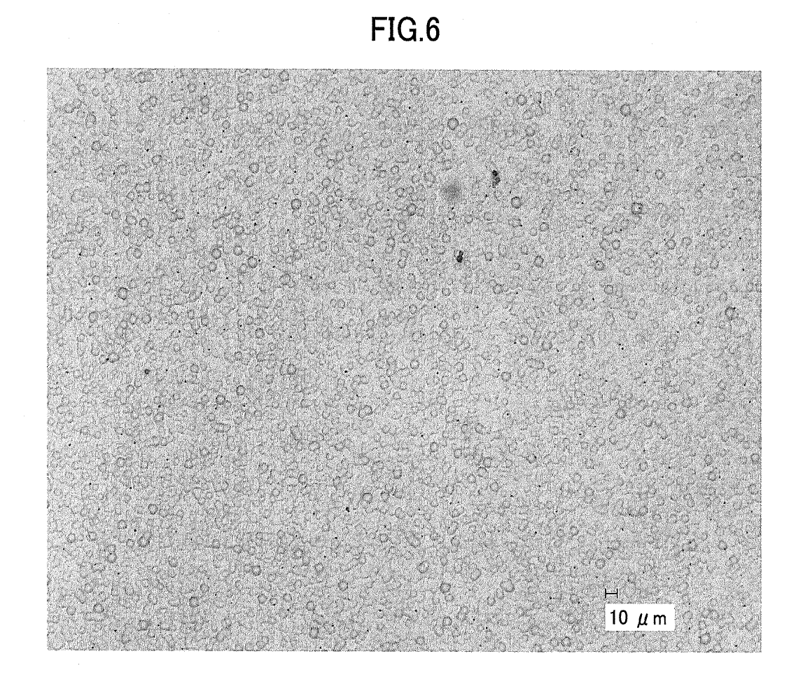

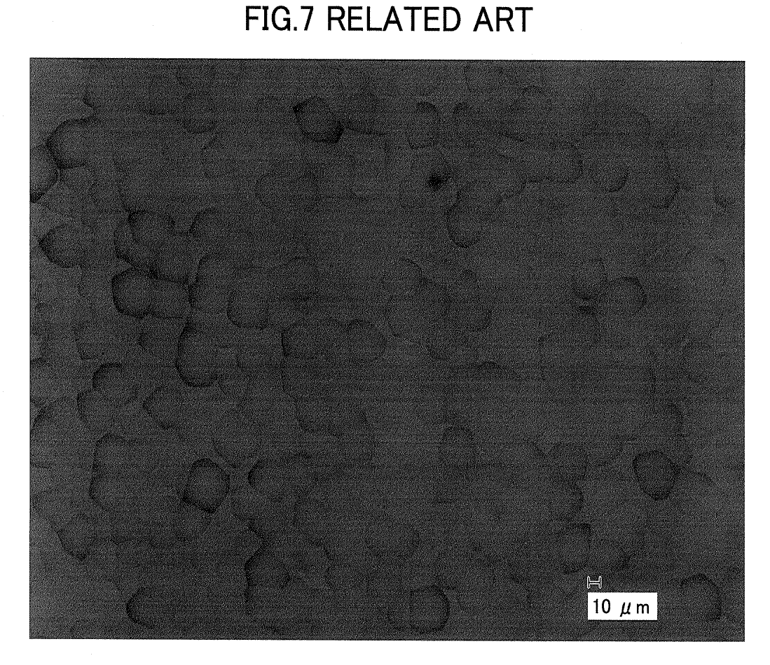

FIG. 6 is a microscope photograph depicting a glass surface obtained by a secondary etching treatment after the frost treatment shown in FIG. 4. FIG. 7 is a microscope photograph depicting a glass surface obtained by a secondary etching treatment after the frost treatment shown in FIG. 5. In the secondary etching treatment shown in FIG. 6 and the secondary etching treatment shown in FIG. 7, the same etching liquid was used.

When FIG. 6 and FIG. 7 are compared, it is clear that, a rugged shape of the glass surface obtained by the secondary etching treatment greatly depends on a rugged shape of the glass surface obtained by the frost treatment.

According to the embodiment, by using an etching liquid containing potassium fluoride for a masking agent in the frost treatment, the pores obtained by the frost treatment can be made finer. Because the pore representative diameter is less than four times the width A1 of the green pixel 1G, an excellent performance of controlling against glittering of image can be obtained. Moreover, because a number of ridges surrounding pores is great and the ridges are sharp, an external light is diffused and reflected at the ridge, and an excellent antiglare property can be obtained.

On the glass surface obtained by the frost treatment, the pore representative diameter is sufficiently smaller than four times the width A1 of the green pixel 1G. Even if the representative diameter is a little greater, there is no problem. In contrast, in the glass surface obtained by the frost treatment, the number of ridges may be too great, or the ridges may be too sharp. Thus, after the frost treatment, the secondary etching treatment is performed.

Because, in the secondary etching treatment, the number of ridges decreases, or the sharpness of the ridges is reduced, a diffusion of a light emitted from a green pixel 1G and transmitting through the rugged surface 21 (transmission haze) can be reduced. Thus, blur of an image can be controlled, and an excellent image quality is obtained. Moreover, when the number of ridges decreases or the sharpness of the ridges is reduced, an excellent anti-scratching property can be obtained.

In this way, the rugged surface 21, in which the transmission haze is 28% or less, the pore representative diameter is less than 12 μm, and the area ratio (A/60000) is 1.02 or more and 1.07 or less, is formed. According to the aforementioned configurations, for each of controlling against glittering of image, an antiglare property, an anti-scratching property, and an image quality, an excellent performance can be obtained.

### EXAMPLES

In Examples 1 to 15, glass articles were manufactured under the same condition except for a condition for a frost treatment, a processing time for a secondary etching treatment, presence or absence of a chemical strengthening processing, and presence or absence of an antifouling film, and evaluated. Examples 1 to 8 are practical examples, and Examples 9 to 15 are comparative examples.

(1) Manufacturing of Glass Articles

### Example 1

On one of main surfaces of a glass plate formed of an aluminosilicate glass, a rugged surface was formed by a frost treatment and a secondary etching treatment. In the frost treatment, an entire glass plate was immersed in a mixed aqueous solution in which hydrogen fluoride and potassium fluoride were mixed with a mass ratio of 1:1.25. In the subsequent secondary etching treatment, the entire glass plate was immersed in an aqueous solution with a main ingredient of hydrogen fluoride. A part of the glass plate, on which the frost treatment and the secondary etching treatment were not performed, was covered with a protection film in advance. Afterwards, the protection film was removed, the glass plate was washed, and the glass plate was served to a chemical strengthening processing.

The chemical strengthening processing was performed by immersing the entire glass plate in a molten salt including potassium (K) ions at 450° C. for 80 minutes. After the chemical strengthening processing, on a rugged surface of the glass plate, as a functional film, a low reflection film and an antifouling film were deposited in this order.

The low reflection film is formed on the rugged surface of the glass plate as follows. First, introducing a mixed gas, in which an oxygen gas of 10 volume % was mixed in an argon gas, using a niobium oxide target (trade name: NBO target, by AGC Ceramics Co., Ltd.), under a condition of a pressure of 0.3 Pa, a frequency of 20 kHz, a power density of 3.8 W/cm², and an inverting pulse width of 5 μsec, a pulse sputtering was performed, to form a high refraction index layer including niobium oxide (niobia) with a thickness of 13 nm on the rugged surface of the glass plate.

Next, introducing a mixed gas, in which an oxygen gas of 40 volume % was mixed in an argon gas, using a silicon target, under a condition of a pressure of 0.3 Pa, a frequency of 20 kHz, a power density of 3.8 W/cm², and a pulse width of 5 μsec, a pulse sputtering was performed, to form a low refraction index layer including silicon oxide (silica) with a thickness of 30 nm on the high refraction index layer.

Then, introducing a mixed gas, in which an oxygen gas of 10 volume % was mixed in an argon gas, using a niobium oxide target (trade name: NBO target, by AGC Ceramics Co., Ltd.), under a condition of a pressure of 0.3 Pa, a frequency of 20 kHz, a power density of 3.8 W/cm², and an inverting pulse width of 5 μsec, a pulse sputtering was performed, to form a high refraction index layer including niobium oxide (niobia) with a thickness of 110 nm on the low refraction index layer.

Next, introducing a mixed gas, in which an oxygen gas of 40 volume % was mixed in an argon gas, using a silicon target, under a condition of a pressure of 0.3 Pa, a frequency of 20 kHz, a power density of 3.8 W/cm², and a pulse width of 5 μsec, a pulse sputtering was performed, to form a low refraction index layer including silicon oxide (silica) with a thickness of 90 nm.

In this way, the low reflection film, in which niobium oxide (niobia) layers and silicon oxide (silica) layers were laminated (four layers in total), was formed.

The antifouling film was formed on the low reflection film as follows. First, as an evaporation material, a fluorine-containing organic silicon compound (trade name: KY-185, by Shin-Etsu Chemical Co., Ltd.) was introduced into a heating container. Afterwards, an inside of the heating container was degassed by a vacuum pump for 10 hours or more, to remove a solvent in a solution, and thereby a composition for forming a fluorine-containing organic silicon compound film was obtained.

Next, the heating container including the composition for forming a fluorine-containing organic silicon compound film was heated up to 270° C. After reaching 270° C., the state was maintained for 10 minutes until a temperature became stable.

Then, the composition for forming a fluorine-containing organic silicon compound film was supplied from a nozzle, connected to the heating container including the composition for forming a fluorine-containing organic silicon compound film, to the rugged surface of the glass plate arranged in a vacuum chamber, and a deposition was performed.

Deposition was performed, measuring a film thickness by a crystal oscillator arranged in the vacuum chamber. The deposition was performed until a film thickness of the fluorine-containing organic silicon compound film formed on the glass plate became 10 nm.

When the film thickness of the fluorine-containing organic silicon compound film became 10 nm, the supply of a raw material from the nozzle was stopped, and the glass plate on which the fluorine-containing organic silicon compound film was formed was extracted.

The extracted glass plate, on which the fluorine-containing organic silicon compound film was formed, was arranged on a hot plate with a film surface directed upward, and was subjected to a heat treatment in the atmosphere at 150° C. for 60 minutes.

### Example 2

A glass article was manufactured in the same way as in Example 1, except that as the functional film, only the low reflection film was formed and the antifouling film was not formed.

### Example 3

A glass article was manufactured in the same way as in Example 1, except that, after processing the rugged surface, the functional film was formed without performing the chemical strengthening processing.

### Example 4

A glass article was manufactured in the same way as in Example 1, except that in the frost treatment the mass ratio of the masking agent (potassium fluoride) to hydrogen fluoride, i.e. masking agent/hydrogen fluoride, was reduced to 1.20.

### Example 5

A glass article was manufactured in the same way as in Example 1, except that in the frost treatment the mass ratio of the masking agent (potassium fluoride) to hydrogen fluoride, i.e. masking agent/hydrogen fluoride, was reduced to 1.15.

### Example 6

A glass article was manufactured in the same way as in Example 1, except that the processing time of the secondary etching treatment was set longer so that the transmission haze of the glass article decreased to 16.9.

### Example 7

A glass article was manufactured in the same way as in Example 6, except that the processing time of the secondary etching treatment was set further longer so that the transmission haze of the glass article further decreased to 5.4.

### Example 8

A glass article was manufactured in the same way as in Example 7, except that the processing time of the secondary etching treatment was set further longer so that the transmission haze of the glass article further decreased to 2.2.

### Example 9

A glass article was manufactured in the same way as in Example 1, except that in the frost treatment ammonium fluoride was used for the masking agent instead of potassium fluoride.

### Example 10

A glass article was manufactured in the same way as in Example 9, except that as the functional film, only the low reflection film was formed and the antifouling film was not formed.

### Example 11

A glass article was manufactured in the same way as in Example 9, except that the processing time of the secondary etching treatment was set shorter so that the transmission haze of the glass article increased to 3.7.

### Example 12

A glass article was manufactured in the same way as in Example 1, except that in the frost treatment the mass ratio of the masking agent (potassium fluoride) to hydrogen fluoride, i.e. masking agent/hydrogen fluoride, was increased to 2.00.

### Example 13

A glass article was manufactured in the same way as in Example 12, except that the processing time of the secondary etching treatment was set shorter so that the transmission haze of the glass article increased to 39.7.

### Example 14

A glass article was manufactured in the same way as in Example 13, except that the processing time of the secondary etching treatment was set further shorter so that the transmission haze of the glass article increased to 54.3.

### Example 15

A glass article was manufactured in the same way as in Example 14, except that the processing time of the secondary etching treatment was set further shorter so that the transmission haze of the glass article increased to 74.1.

### Example 16

A glass article was manufactured in the same way as in Example 1, except that the frost treatment and the secondary etching treatment were not performed on the glass plate.

(2) Method of Evaluation

A method of evaluation for characteristics of the glass articles manufactured in Examples 1 to 16 will be described.

[Measurement Points]

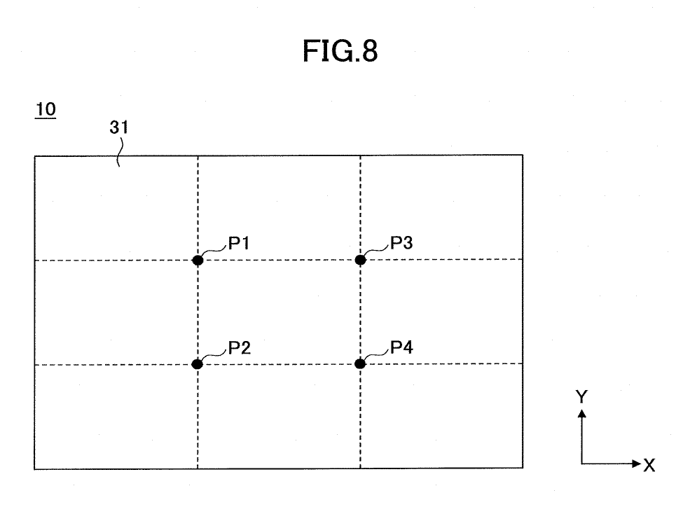

FIG. 8 is a plan view depicting measurement points at which characteristic values of the glass articles manufactured in Examples 1 to 16 were measured. As illustrated in FIG. 8, the characteristic values of the glass articles were measured at the four measurement points, P1 to P4, on a surface of the functional film. Average values of measured values are shown in TABLE 1. The four measurement points, P1 to P4, were defined to be intersection points of two lines, which trisect the glass article in the longitudinal direction (X-direction), with two lines, which trisect the glass article in the width direction that is orthogonal to the longitudinal direction (Y-direction).

[Transmission Haze]

The transmission haze was measured using a haze meter (MODEL HZ-V3: by Suga Test Instruments Co., Ltd.), and the measurement was performed in conformity with JIS K 7136:2000 (ISO 14782:1999).

[Measurement of Rugged Shape of Surface of Functional Film]

The rugged shape of the surface of the functional film was measured using a laser microscope (Trade name: VK-9700 by Keyence Corporation) at 50-fold magnification. Based on results of measurement, pore representative diameters and area ratios (A/60000) were calculated.

[Glittering of Image]

Glittering of an image was visually evaluated for the glass article placed on an image display device in which an entire screen was caused to display with green. For the image display device, an LCD (liquid Crystal Display) device with a pixel resolution of 264 ppi was used. A width of a green pixel was 3.2 μm.

Note that in TABLE 1 that shows result of evaluation, which is shown below, “small” means that glittering of an image was visually recognized to be small, and “great” means that glittering of an image was visually recognized to be great.

[Image Quality (Blur of Image)]

The image quality was evaluated by arranging horizontally the glass article, which was an object to be measured, via a spacer with a thickness of 3 cm, on an upper surface of a bar-chart (High resolution chart type I, by Dai Nippon Printing Co., Ltd.) arranged horizontally, observing a pattern of the bar-chart via the glass article, and determining whether black lines with a resolution of 2000 TVL could be individually distinguished. Note that in TABLE 1 that shows result of evaluation, which is shown below, “good” means that black lines could be individually distinguished, “fair” means that black lines could be distinguished but contours were obscure, and “poor” means that black lines could not be distinguished.

[Antiglare Property]

The antiglare property was evaluated by arranging horizontally a glass article on an LCD having a pixel resolution of 264 ppi and arranged horizontally, and determining whether an image displayed on the LCD could be recognized via the glass article, when the glass article was irradiated with a light with an intensity of 1500 lx from a fluorescent lamp arranged above the glass article. Note that in TABLE 1 that shows result of evaluation, which is shown below, “good” means that a displayed image could be recognized, and “poor” means that the displayed image was difficult to recognize.

[Pencil Hardness]

The pencil hardness was measured in conformity with JIS K5600-5-4:1999 (ISO 15184:1996) “scratch hardness (pencil method)”.

[Martens Hardness]

The Martens hardness was measured using an indentation measurement instrument (PICODENTOR HM500 by Fischer Instruments K.K.). The glass article was placed with the functional film facing upward, and an indenter was pushed into the glass article from up above. A measuring load was set to 0.03 mN/5 sec, i.e. the measuring load was increased from 0 to 0.03 mN for 5 seconds, then the measuring load was retained at 0.03 mN, and finally the measuring load was reduced from 0.03 mN to 0.

(3) Result of Evaluation

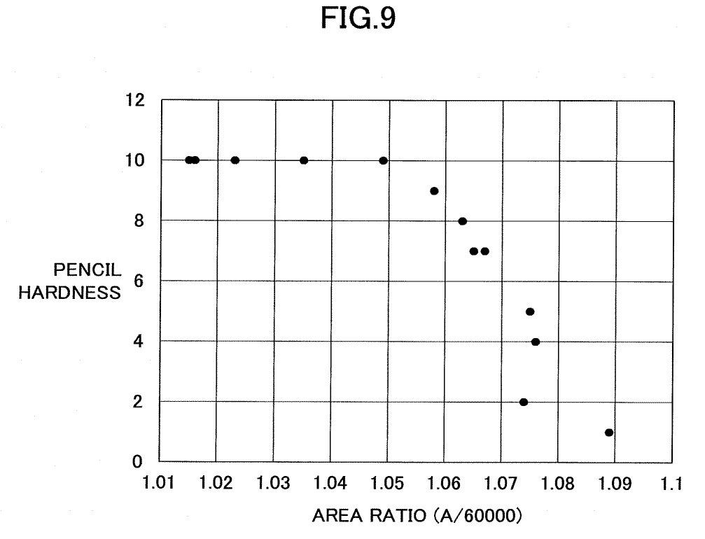

Results of evaluation for the glass articles manufactured in Examples 1 to 16 are shown in TABLE 1 along with the manufacturing conditions. Moreover, a relation between the area ratios (A/60000) of the glass articles manufactured in Examples 1 to 15 and the pencil hardness is shown in FIG. 9.

TABLE 1

| | | | | chemical strengthening | | | |
|---|---|---|---|---|---|---|---|
| | | | | processing | | presence | |
| | frost treatment | | pore | | surface | of | |
| | masking | mass | representative | | compressive | antiglare | transmission |
| | agent | ratio | diameter (μm) | presence | stress (MPa) | film | haze (%) |
| ex. 1 | KF | 1.25 | 6.3 | YES | 752 | YES | 25.3 |
| ex. 2 | KF | 1.25 | 6.4 | YES | 751 | NO | 25.3 |
| ex. 3 | KF | 1.25 | 6.2 | NO | — | YES | 25.4 |
| ex. 4 | KF | 1.20 | 6.8 | YES | 751 | YES | 24.8 |
| ex. 5 | KF | 1.15 | 7.4 | YES | 752 | YES | 24.9 |
| ex. 6 | KF | 1.25 | 7.3 | YES | 749 | YES | 16.9 |
| ex. 7 | KF | 1.25 | 9.2 | YES | 752 | YES | 5.4 |
| ex. 8 | KF | 1.25 | 11.4 | YES | 753 | YES | 2.2 |
| ex. 9 | NH₄F | 1.25 | 40.3 | YES | 752 | YES | 1.4 |
| ex. 10 | NH₄F | 1.25 | 39.8 | YES | 751 | NO | 1.5 |
| ex. 11 | NH₄F | 1.25 | 28.7 | YES | 753 | YES | 3.7 |
| ex. 12 | KF | 2.00 | 5.9 | YES | 751 | YES | 29.8 |
| ex. 13 | KF | 2.00 | 5.4 | YES | 751 | YES | 39.7 |
| ex. 14 | KF | 2.00 | 4.7 | YES | 753 | YES | 54.3 |
| ex. 15 | KF | 2.00 | 4.1 | YES | 752 | YES | 74.1 |
| ex. 16 | — | — | — | YES | 748 | YES | 0.0 |

| | | | | image | | |
|---|---|---|---|---|---|---|
| | | Martens | | quality | | |
| | area ratio | hardness | pencil | (blur of | antiglare | glittering |
| | (A/60000) | (GPa) | hardness | image) | property | of image |
| ex. 1 | 1.065 | 2.9 | 7H | good | good | small |
| ex. 2 | 1.067 | 2.9 | 7H | good | good | small |
| ex. 3 | 1.065 | 3.0 | 7H | good | good | small |
| ex. 4 | 1.063 | 2.9 | 8H | good | good | small |
| ex. 5 | 1.058 | 3.0 | 9H | good | good | small |
| ex. 6 | 1.049 | 3.0 | 10H | good | good | small |
| ex. 7 | 1.035 | 3.1 | 10H | good | good | small |
| ex. 8 | 1.023 | 2.9 | 10H | good | good | small |
| ex. 9 | 1.015 | 3.0 | 10H | good | good | great |
| ex. 10 | 1.016 | 2.9 | 10H | good | good | great |
| ex. 11 | 1.015 | 3.0 | 10H | good | good | great |
| ex. 12 | 1.075 | 3.1 | 5H | fair | good | small |
| ex. 13 | 1.076 | 3.0 | 4H | fair | good | small |
| ex. 14 | 1.074 | 1.8 | 2H | poor | good | small |
| ex. 15 | 1.089 | 3.1 | H | poor | good | small |
| ex. 16 | 1.000 | 3.2 | 10H | good | poor | small |

As shown in TABLE 1, in Examples 1 to 8, by using potassium fluoride for a masking agent in the frost treatment, pores obtained by the frost treatment were made finer, and afterwards a number of ridges and sharpness of the ridges were made proper by the secondary etching treatment. As a result, the transmission haze was 28% or less, a blur of an image could be controlled, and the image quality was excellent. The pore representative diameter was less than 12 μm, which was less than four times the width of the green pixel 3.2 μm, and the glittering of an image was small. Moreover, the area ratio (A/60000) was 1.02 or more, and the antiglare property was excellent. Furthermore, because the area ratio (A/60000) was 1.07 or less, the pencil hardness was 7H or more, and the anti-scratching property was excellent.

In contrast, in Examples 9 to 11, different from Examples 1 to 8, ammonium fluoride was used for the masking agent in the frost treatment. As a result, the pore representative diameter was 12 μm or more, which was greater than four times the width of the green pixel 3.2 μm, and the glittering of an image was great. Moreover, the area ratio (A/60000) was less than 1.02, and the antiglare property was poor.

In contrast, in Examples 12 to 15, in the same way as Examples 1 to 8, potassium fluoride was used for the masking agent in the frost treatment. However, in the secondary etching treatment, the number of ridges and the sharpness of the ridges were not sufficiently made proper. As a result, the transmission haze exceeds 28%, an image was blurred and inferior as compared with that in Examples 1 to 8, and the image quality was poor. Moreover, the area ratio (A/60000) exceeds 1.07, the pencil hardness was less than 7H, and the anti-scratching property was poor.

Moreover, in FIG. 16, because the frost treatment and the secondary etching treatment were not performed on the glass plate, a light from a fluorescent lamp was reflected on the glass plate, an image displayed on the LCD was difficult to recognize, and the anti-glare property was poor.

As described above, embodiments and the like of glass articles were described. However, the present invention is not limited to the embodiments or the like. Various variations and enhancements may be made without departing from the scope of the present invention.

### REFERENCE SIGNS LIST

10 glass article
20 glass plate
21 rugged surface
30 functional film
31 surface
40 low reflection film
50 antifouling film

What is claimed is:

1. A glass article comprising:
a glass plate including a rugged surface configured to diffuse and reflect an external light formed on at least one of main surfaces; and
a functional film formed on the rugged surface,
wherein a transmission haze of the glass article is 28% or less,
wherein on a surface of the functional film opposite to the glass plate, within a region with a visual field area of 60000 μm² observed by using a laser microscope, a pore representative diameter is less than 12 μm, and
wherein an area ratio of a surface area A (pre) of the surface of the functional film within the region to the visual field area (A/60000) is 1.02 or more and 1.07 or less.

2. The glass article according to claim 1,
wherein the area ratio (A/60000) is 1.02 or more and 1.06 or less.

3. The glass article according to claim 1,
wherein the transmission haze of the glass article is 20% or less.

4. The glass article according to claim 1,
wherein a Martens hardness of the glass article is 2.0 GPa or more.

5. The glass article according to claim 1,
wherein the functional film includes a low reflection film configured to control against a reflection of an external light.

6. The glass article according to claim 5,
wherein the functional film further includes an antifouling film configured to control against a fouling of the glass article, and
wherein the antifouling film is formed on a surface of the low reflection film opposite to the glass plate.

7. The glass article according to claim 1,
wherein the glass plate is formed of a soda lime glass or an aluminosilicate glass.

8. The glass article according to claim 1,
wherein the glass plate includes a compressive stress layer on the main surface, and
wherein a surface compressive stress of the compressive stress layer is 600 MPa or more.

9. A display device comprising the glass article according to claim 1.

10. The display device according to claim 9,
wherein the display device is an apparatus for vehicle.
